(19) United States
(12) Patent Application Publication
(10) Pub. No.: US 2011/0163413 A1
(43) Pub. Date: Jul. 7, 2011

(54) RF SEMICONDUCTOR DEVICE AND FABRICATION METHOD THEREOF

(75) Inventors: Ki Joong Kim, Hwaseong (KR); Jin Seok Kim, Daejeon (KR); Kwang Sic Kim, Yongin (KR); Youn Suk Kim, Yongin (KR); Young Sik Kang, Daejeon (KR); Tae Joon Park, Daejeon (KR)

(73) Assignee: SAMSUNG ELECTRO-MECHANICS CO., LTD., Suwon (KR)

(21) Appl. No.: 12/984,041

(22) Filed: Jan. 4, 2011

(30) Foreign Application Priority Data
Jan. 7, 2010 (KR) 10-2010-0001275

(51) Int. Cl. H01L 27/06; H01L 21/02

(52) U.S. Cl. 257/531; 438/382; 257/E21.004; 257/E21.022; 257/E21.008; 257/E27.016

(57) ABSTRACT

A radio frequency (RF) semiconductor device includes a semiconductor substrate, a resistor film formed at one area of the semiconductor substrate, a first metal layer formed on the semiconductor substrate, a dielectric layer formed at least on the lower electrode film, a second metal layer formed on the dielectric layer, a first insulating layer having a first pad via connected with the first metal layer, a capacitor via connected with the second metal layer, and an inductor via connected with the first or second metal layer. a third metal layer includes filling parts that fill the capacitor via and the inductor via, respectively, and a second circuit line. A second insulating layer is formed on the first insulating layer to have a second pad via connected with the first pad via. A bonding pad is formed at the first and second pad vias.

### CROSS-REFERENCE TO RELATED APPLICATIONS

This application claims the priority of Korean Patent Application No. 10-2010-0001275 filed on Jan. 7, 2010, in the Korean Intellectual Property Office, the disclosure of which is incorporated herein by reference.

### BACKGROUND OF THE INVENTION

1. Field of the Invention

The present invention relates to a radio frequency (RF) semiconductor device and, more particularly, to an RF semiconductor device that can be provided as an integrated passive device (IPD) designed and disposed to be useful for an RF power element, and a fabrication method thereof.

2. Description of the Related Art

Recently, the demand for a semiconductor device to have a high level of integration and high operational speeds is rising. However, in the case of the related art semiconductor integrated circuit having a single-layer wiring, a high level of integration in a semiconductor device leads to a reduction in the width of a metal wiring in the wake of a decrease in an occupancy area, which results in an increase in the electric resistance of the wiring and power consumption.

Thus, a multi-layer wiring has been proposed in order to improve the operational speed thereof, while restraining to its maximum level the increase in the electric resistance of the wiring according to the high level of integration.

A transmission stage of a mobile communication terminal such as a mobile phone employs a power amplifier (PA) in order to amplify the power of a transmission signal. The power amplifier is supposed to amplify the transmission signal to have suitable power. Research has continued to effectively implement a transformer that controls an output of such power amplification; however, the implementation of such a transformer triggers a problem in the generation of a harmonic component in the output signal.

In general, the foregoing power amplifier and a power combining circuit are necessarily employed in a transmission/reception circuit such that they are integrated on a single substrate, and in this case, the power amplifier may be formed through a complementary metal oxide semiconductor (CMOS) process, and the power combining circuit may be formed through an integrated passive device (IPD) process.

However, the structure in which a power line of an external driving power source is formed on the power combining device degrades harmonics characteristics, in particular, secondary harmonics characteristics, thereby failing to satisfy consumer demand.

The integrated passive device using the related art CMOS process technique has a limitation in structuring each passive device in consideration of their characteristics. For example, in case of an inductor element, its RF performance deteriorates due to an air bridge, and in the case of a capacitor, because a capacitor area is determined by an upper conducting wire, an elaborate deposition process needs to be performed, increasing a conducting wire resistance. Also, because a copper (Cu) conducting wire is oxidized in forming a pad, it is difficult to plate gold (Au) thereon.

### SUMMARY OF THE INVENTION

An aspect of the present invention provides a radio frequency (RF) semiconductor device capable of precisely controlling a line width and height while minimizing a processing deviation by using a semiconductor process and implementing an integrated passive device to fit an RF performance.

Another aspect of the present invention provides a method for fabricating the RF semiconductor device.

According to an aspect of the present invention, there is provided an RF semiconductor device including: a semiconductor substrate; a resistor film formed at one area of the semiconductor substrate and provided as a resistor element; a first metal layer formed on the semiconductor substrate and provided as a lower electrode film for a first circuit line to which the resistor film is connected and for a capacitor; a dielectric layer formed at least on the lower electrode film; a second metal layer formed on the dielectric layer and provided as an upper electrode film for a portion connected with the first metal layer and for the capacitor; a first insulating layer having a first pad via connected with the first metal layer, a capacitor via connected with the second metal layer, and an inductor via connected with the first or second metal layer; a third metal layer including filling parts that fill the capacitor via and the inductor via, respectively, and providing a second circuit line formed on the first insulating layer and connected with the filling part of the capacitor via and an inductor line connected with the filling part of the inductor via; a second insulating layer formed on the first insulating layer such that the second insulating layer covers the third metal layer and having a second pad via connected with the first pad via; and a bonding pad formed at the first and second pad vias such that the bonding pad is connected with the first metal layer.

The semiconductor substrate may be a GaAs substrate or a high resistance silicon substrate. The dielectric layer may include a silicon nitride film.

The first metal layer may include a titanium (Ti) layer formed on the semiconductor substrate and a copper (Cu) layer formed on the Ti layer.

At least one of the second and third metal layers may include a seed metal layer and a plated layer formed on the seed metal layer. In this case, the seed metal layer may be made of Ti/Cu and the plated layer may be made of Cu.

The inductor via may be formed at a portion of the second metal layer to which the first metal layer is connected.

The dielectric layer may be formed on the semiconductor layer such that an area of the first metal layer which corresponds to the first pad via and an area of the first metal layer which is connected with the second metal layer are exposed.

At least one of the first and second insulating layers may include benzocyclobutene (BCB). The bonding pad may include nickel (Ni)/gold (Au).

The RF semiconductor device may further include: a shielding layer formed on an upper surface of the second insulating layer which corresponds to the inductor line or the second circuit line. In this case, the shielding layer may be connected with the bonding pad so as to be grounded.

According to another aspect of the present invention, there is provided a method for fabricating an RF semiconductor device including: preparing a semiconductor substrate; forming a resistor film, provided as a resistor element, at one area of the semiconductor substrate; forming a first metal layer, provided as a lower electrode film for a first circuit line to which the resistor film is connected and for a capacitor, on the semiconductor substrate; forming a dielectric layer on the semiconductor substrate such that the first metal layer is exposed from one region; forming a second metal layer, provided as an upper electrode film for a portion connected with the first metal layer and for the capacitor, on the dielectric layer; forming a first insulating layer having a first pad via exposing the first metal layer, a via exposing the upper electrode film, and an inductor via exposing the second metal layer; forming a third metal layer including filling parts that fill the capacitor via and the inductor via, respectively, and providing a second circuit line connected with the filling part of the capacitor via and an inductor line connected with the filling part of the inductor via on the first insulating layer; forming a second insulating layer having a second pad via connected with the first pad via on the first insulating layer to cover the third metal layer; and forming a bonding pad at the first and second pad vias such that the bonding pad is connected with the first metal layer.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a side sectional view showing a radio frequency (RF) semiconductor device according to one exemplary embodiment of the present invention;

FIGS. 2 to 8 are sectional views sequentially showing the process of fabricating the RF semiconductor device illustrated in FIG. 1; and

FIG. 9 is a side sectional view showing a radio frequency (RF) semiconductor device according to another exemplary embodiment of the present invention.

### DETAILED DESCRIPTION OF THE PREFERRED EMBODIMENT

Exemplary embodiments of the present invention will now be described in detail with reference to the accompanying drawings. The invention may, however, be embodied in many different forms and should not be construed as being limited to the embodiments set forth herein. Rather, these embodiments are provided so that this disclosure will be thorough and complete, and will fully convey the scope of the invention to those skilled in the art. In the drawings, the shapes and dimensions may be exaggerated for clarity, and the same reference numerals will be used throughout to designate the same or like components.

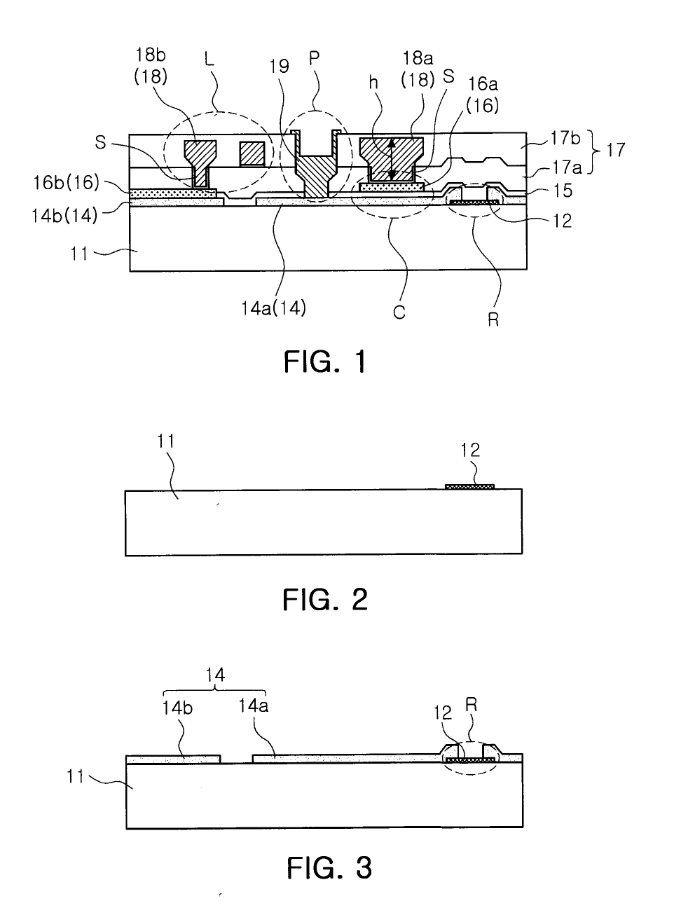

FIG. 1 is a side sectional view showing a radio frequency (RF) semiconductor device according to one exemplary embodiment of the present invention.

As shown in FIG. 1, an RF semiconductor device 10 includes a semiconductor substrate 11, an inductor element (L), a capacitor element (C), and a resistor element (R) formed on the semiconductor substrate 11.

A high resistance semiconductor substrate may be used as the semiconductor substrate 11 in order to minimize a loss caused by the substrate. For example, the semiconductor substrate 11 may be a GaAs substrate or a high resistance silicon substrate. A resistor film 12 provided as the resistor element (R) is formed at one region of the semiconductor substrate 11. The resistor film 12 may be made of Ni—Cr.

A first metal layer 14 is formed on the semiconductor substrate 11. The first metal layer may be formed through a conventional deposition process and may be a dual layer including a titanium (Ti) layer for reinforcing bonding and a copper (Cu) layer having a good electrical conductivity.

A portion 14a of the first metal layer 14 is provided as a lower electrode film for a first circuit line to which the resistor film 12 is connected and for the capacitor (C). Another portion 14b of the first metal layer 14 may be provided as a portion connected with the inductor element (L).

A dielectric layer 15 is formed on the lower electrode film 14a. The dielectric layer 15 may be a silicon nitride film. The dielectric layer 15 may be provided to an area other than a portion to be connected with a circuit of a different level. For example, as shown in FIG. 1, the dielectric layer 15 may be formed to expose an area, which corresponds to the first pad via, of the first metal layer 14a and an area connected with a second metal layer 16b.

In the present exemplary embodiment, a second metal layer 16 is formed on the dielectric layer 15. The second metal layer 16 includes the portion 16b connected with the first metal layer 14b and an upper electrode film 16a for the capacitor (C).

A first insulating layer 17a is formed on the second metal layer 16. The first insulating layer 17a forms a third metal layer 18 or a via for a pad (P). The insulating layer 17a includes a first pad via connected with the first metal layer 14, a capacitor via connected with the second metal layer, and an inductor via connected with the first or second metal layer 14 or 16. As shown in FIG. 1, the inductor via may be formed on the portion 16b, which is connected with the first metal layer, of the second metal layer 16.

Preferably, the first insulating layer 17a may contain benzocyclobutene (BCB). In this case, the BCB has a low permittivity (or dielectric constant), enhancing the reliability of the inductor element (L).

A third metal layer 18 is formed on the first insulating layer 17a and provides filling parts that fill the capacitor via and the inductor via. The third metal layer 18 includes a second circuit line 18a and an inductor line 18b.

The second circuit line 18a is connected with the filling part of the capacitor via on the first insulating layer 17a, and the inductor line 18b is connected with the filling part of the inductor via on the first insulating layer 17a.

In the present exemplary embodiment, although not shown, the RF semiconductor device may include a coplanar waveguide (CPW) transmission line and may be implemented when the third metal layer 18 is formed.

Preferably, the third metal layer 18 may include a seed metal layer (S) and a plated layer formed on the seed metal layer. In this case, the seed metal layer is made of titanium (Ti))/copper (Cu), and the plated layer may be made of copper (Cu). The plated layer may be formed to have a thickness of 10 μm or more at the via area by using a plating process.

The second metal layer 16 may also have the structure of seed metal layer/plated layer in a similar manner. Preferably, the second metal layer 16, providing the upper electrode film, may have a plated layer having a thickness of about 2 μm or more in order to reduce a conducting wire resistance.

In the present exemplary embodiment, a second insulating layer 17b is formed on the first insulating layer 17a to cover the third metal layer 18. Also, the second insulating layer 17b includes a second pad via connected with the first pad via. A bonding pad (P) is formed at the first and second pad vias such that the bonding pad (P) is connected with the first metal layer 14a. The bonding pad (P) may include nickel (Ni) and gold (Au).

The RF semiconductor device, namely, the integrated passive device, according to the present exemplary embodiment, provides many advantages. For example, in the case of the inductor, it is implemented as the first and third metal layers and formed on the second insulating layer 17b interposed therebetween. Because the inductor element (L) is formed on the layer of low permittivity such as BCB without an air bridge at a crossing of the inductor line, the reliability of the inductor element (L) can be significantly improved.

Also, at the capacitor element (C), the lower electrode film is formed by depositing metal having high conductivity such as copper (Cu), and the upper electrode film may be formed as a copper plated layer. In general, the upper electrode film determines the capacitor area (C), for which, thus, an elaborate deposition process is performed, but in the present exemplary embodiment, the upper electrode film is formed by using the process of plating metal having good electrical conductivity such as copper (Cu) in order to reduce a conducting wire resistance.

The pad (P) is formed as a plated layer of metal such as copper (Cu). In this case, in order to solve the problems of copper oxidation and the difficulty in plating gold (Au) and its reliability, the pad (P) may be directly formed on the first metal layer 14 by using metal plating of gold (Au) by preparing the pad vias at the first and second insulating layers 17a and 17b. In addition, a protection layer may be formed by using an insulating layer such as BCB to remarkably improve RF performance.

FIGS. 2 to 8 are sectional views sequentially showing the process of fabricating the RF semiconductor device illustrated in FIG. 1.

As shown in FIG. 2, the semiconductor substrate 11 is prepared, and the resistor film 12, provided as a resistor element, is formed on one area of the semiconductor substrate 11.

The semiconductor substrate 11 may be a GaAs substrate or a high resistance silicon substrate. The resistor film 12 provided as the resistor element (R) is formed on one area of the semiconductor substrate 11.

Referring to the formation of the resistor film 12, after a photoresist pattern exposing an area where the resistor film 12 is to be formed is formed, a resistance material is deposited, and the photoresist is then lifted off, thus forming the resistor film 12. The resistor film 12 may be made of nickel (Ni) and chromium (Cr), and may have a thickness ranging from 100 Å to 1,500 Å. Preferably, the resistor film 12 has a thickness of about 500 Å.

As shown in FIG. 3, the first metal layer 14 is formed on the semiconductor substrate 11.

The first metal layer 14 may provide the area 14a provided as the lower electrode film for the first circuit line with which the resistor film 12 is connected and for the capacitor and the area 14b to be connected with the inductor.

As for the formation of the first metal layer 14, a photoresist pattern exposing an area where the first metal layer 14 is to be formed is formed, a metal material is deposited, and the photoresist pattern is then lifted off, thus forming the first metal layer 14. The material for forming the first metal layer 14 may be Ti/Cu, and preferably, may be Ti/Cu/Ni/Au. The first metal layer 14 may be formed to have a thickness of about 1 μm overall.

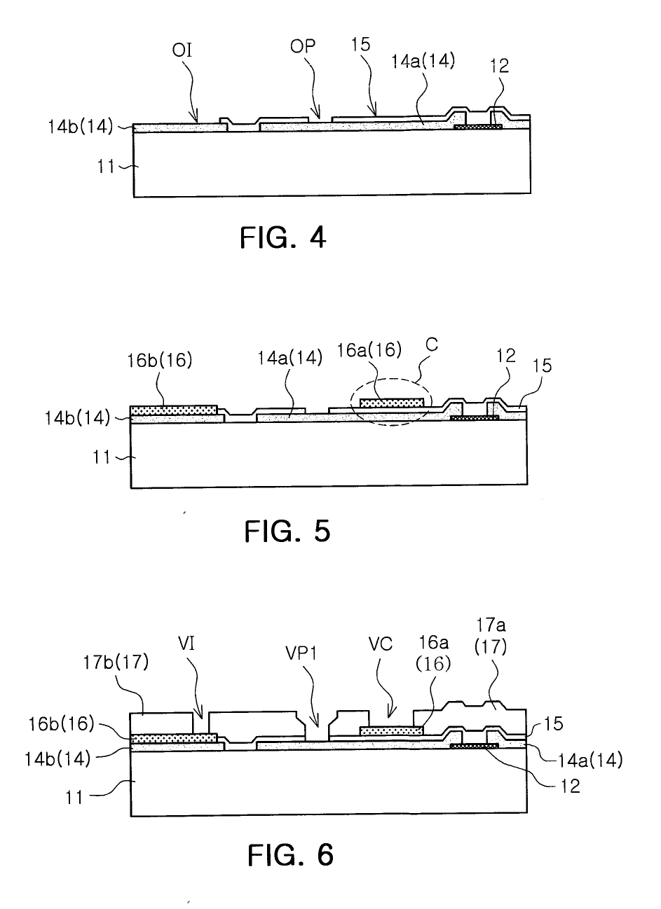

And then, as shown in FIG. 4, the dielectric layer 15 is formed on the semiconductor substrate 11.

The dielectric layer 15 may be formed such that an area OP, corresponding to the first pad, of the first metal layer 14a and an area OI connected with the second metal layer 16b are exposed.

As for the formation of the dielectric layer 15, a photoresist pattern exposing an area where the dielectric layer 15 is to be formed is formed, a dielectric material is deposited, and the photoresist pattern is then lifted off, thus forming the dielectric layer 15. The dielectric layer 15 may be a silicon nitride film. The dielectric layer 15 may have a difference in thickness according to its position, but it may have a thickness ranging from 1,000 Å to 3,000 Å.

Subsequently, as shown in FIG. 5, the second metal layer 16 is formed.

The second metal layer 16 provides the portion 16b connected with the first metal layer 14b and the upper electrode film 16a formed on the dielectric layer 15 for the capacitor. Because the second metal layer 16 provides the upper electrode film 16b of the capacitor C and provides a power feeding part of the inductor (I) along with the first metal layer 14, a contact resistance can be reduced and a current regulation capacity can be increased.

As for the formation of the second metal layer 16, a photoresist pattern exposing an area where the second metal layer 16 is to be formed is formed, a seed metal (e.g., Ni) is deposited and plated with, for example, copper (Cu), and the photoresist pattern is then lifted off, thus forming the second metal layer.

Through this process, the capacitor area (C) may be provided. The second metal layer 16 may include a Ti or Ti/Cu seed metal layer and a Cu plated layer formed on the seed metal layer. The Cu plated layer may have a thickness of about 2 μm or larger. Preferably, the Cu plated layer may have a thickness of 3 μm or larger.

And then, as shown in FIG. 6, the first insulating layer 17a is formed on the second metal layer 16.

The first insulating layer 17a includes the first pad via VP1 exposing the first metal layer 14, the via VC exposing the upper electrode film 16a, and the inductor via VI exposing the second metal layer 16.

The first insulating layer 17a may be made of a BCB material having a low permittivity. The first insulating layer 17a may form the via areas VP1, VC, and VI with photosensitive BCB. The first insulating layer 17a made of BCB may have a thickness ranging from 3 μm to 15 μm, and preferably, it has a thickness of about 5 μm or larger. The size of the first pad via VP1 may be about 25 μm×25 μm.

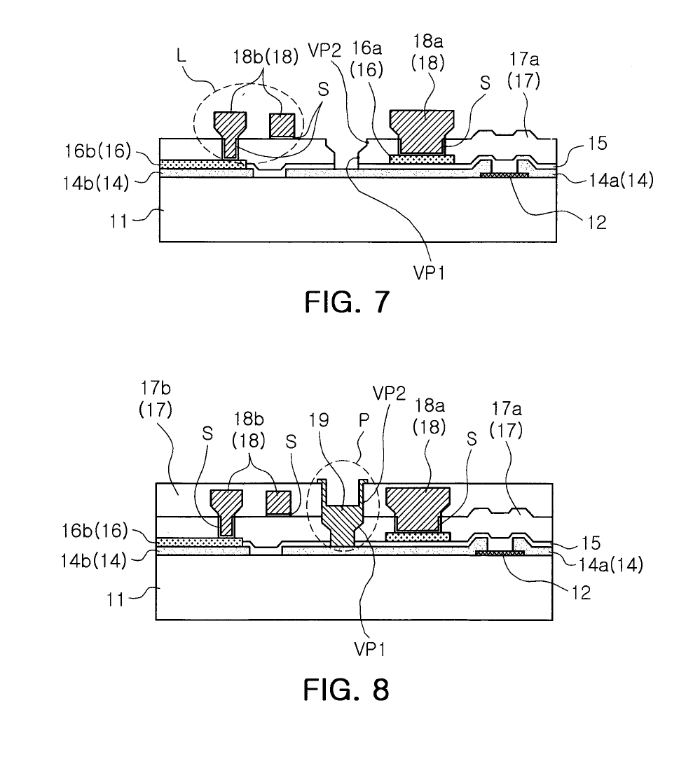

Thereafter, as shown in FIG. 7, the third metal layer 18 is formed. The third metal layer 18 is formed on the first insulating layer 17a and provides filling parts that fill the capacitor via and the inductor via.

Also, the third metal layer 18 provides the second circuit line 18a and the inductor line 18b. In the process of forming the third metal layer 18, a coplanar waveguide (CPW) transmission line may be also formed together.

As for the formation of the third metal layer 18, a photoresist pattern exposing an area where the third metal layer 18 is to be formed is formed, seed metal (e.g., Ni) is deposited and plated with, for example, copper (Cu), and the photoresist pattern is then lifted off, thus forming the second metal layer.

Like the second metal layer 16, the third metal layer 18 may include a Ti or Ti/Cu seed metal layer and a Cu plated layer formed on the seed metal layer. The Cu plated layer may have a thickness of about 5 μm or larger. Preferably, the Cu plated layer may have a thickness of 10 μm or larger.

As shown in FIG. 8, the second insulating layer 17b is formed to cover the third metal layer 18. Subsequently, a bonding pad 19 is formed at the first and second pad vias VP1 and VP2 such that the bonding pad 19 is connected with the first metal layer 14.

The second insulating layer 17b is formed to have the second pad via connected with the first pad via on the first insulating layer 17a. The second insulating layer 17b may form the desired via area VP2I with photosensitive BCB. The second insulating layer 17a may have a thickness ranging from 3 μm to 15 μm, and preferably, it has a thickness of about 5 μm or larger. The size of the first pad via VP1 may be about 25 μm×25 μm. The bonding pad 19 may include the Ti or Ti/Cu seed metal layer and an Ni/Au plated layer formed on the seed metal layer.

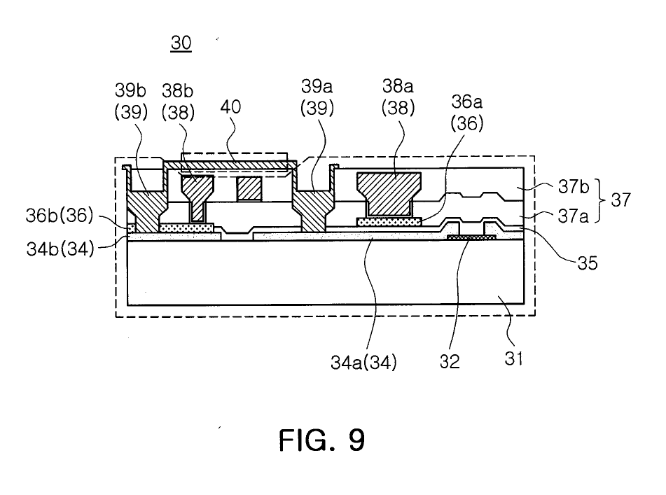

FIG. 9 is a side sectional view showing a radio frequency (RF) semiconductor device according to another exemplary embodiment of the present invention.

With reference to FIG. 9, the RF semiconductor device 30 is an integrated passive device including a semiconductor substrate 31, and an inductor element (L), a capacitor element (C), and a resistor element (R) formed on the semiconductor substrate.

The semiconductor substrate 31 may be a high resistance semiconductor substrate in order to minimize a loss due to the substrate. A resistor film 32 provided as the resistor element (R) is formed on an area of the semiconductor substrate 31. The resistor film 32 may be made of nickel (Ni) and chromium (Cr).

A first metal layer 34 is formed on the semiconductor substrate 31. A portion 34a of the first metal layer 34 is provided as a lower electrode film for a first circuit line to which the resistor film 32 is connected, and for the capacitor (C). Another portion 34b of the first metal layer 34 may be provided as a portion connected with the inductor element (L).

In the present exemplary embodiment, a dielectric layer 35 may be a silicon nitride film. The dielectric layer 35 may be formed such that an area, corresponding to the first pad via, of the first metal layer 34a and an area connected with the second metal layer 36b are exposed.

As shown in FIG. 9, a second metal layer 36 is formed on the dielectric layer 35. The second metal layer 36 includes the portion 36b connected with the first metal layer 34b and an upper electrode film 36a for the capacitor (C).

In the present exemplary embodiment, a first insulating layer 37a includes a first pad via connected with the first metal layer 34, a capacitor via connected with the second metal layer 36, and an inductor via connected with the first or second meta layer 34 or 36.

A third metal layer 38 is formed on the first insulating layer 37a and includes filling parts that fill the capacitor via and the inductor via. The third metal layer 38 provides a second circuit line 38a and an inductor line 38b.

The second circuit line 38a is connected with the filling part of the capacitor via on the first insulating layer 37a, and the inductor line 38b is connected with the filling part of the inductor via on the first insulating layer 37a.

In the present exemplary embodiment, a second insulating layer 37b is formed on the first insulating layer 37a to cover the third metal layer 38. The second insulating layer 37b includes a second pad via connected with the first pad via. The bonding pad (P) is formed at the first and second pad vias such that it is connected with the first metal layer 34a.

A shielding layer 40 may be formed on an area of an upper surface of the second insulating layer 37b corresponding to the area where the inductor line or the second circuit line is positioned. Likewise as in the present exemplary embodiment, the shielding layer 40 may be connected with the bonding pads 39a and 39b so as to be grounded.

As set forth above, according to exemplary embodiments of the invention, a passive device integrated circuit (IC) element suitable for an RF power device which causes less processing deviation and maximizes RF performance can be provided. The inductor, capacitor, and resistor can be implemented by using a tertiary conducting wire (third level) as a conducting wire line.

Also, because a low dielectric material is used between inductors, the RF performance can be maximized, the conductive lines can cross without an air bridge, and the deviation of the conductive lines can be elaborately adjusted (to be within 0.5 μm) compared with the case where an LTCC process is performed.

In addition, the bonding pad can be formed through a plating process so as to be wire-bonded on a primary conductive line, and a protection film for the conductive lines may be formed to have a sufficient thickness (17 μm or larger) with a low dielectric material such as BCB in order to prevent oxidization and obtain reliability.

Moreover, the conductive lines for each passive device can be easily formed as primary, secondary, and tertiary lines by properly using the process of depositing and plating copper (Cu).

While the present invention has been shown and described in connection with the exemplary embodiments, it will be apparent to those skilled in the art that modifications and variations can be made without departing from the spirit and scope of the invention as defined by the appended claims.

What is claimed is:

1. A radio frequency (RF) semiconductor device comprising:
a semiconductor substrate;
a resistor film formed at one area of the semiconductor substrate and provided as a resistor element;
a first metal layer formed on the semiconductor substrate and provided as a lower electrode film for a first circuit line to which the resistor film is connected and for a capacitor;
a dielectric layer formed at least on the lower electrode film;
a second metal layer formed on the dielectric layer and provided as an upper electrode film for a portion connected with the first metal layer and for the capacitor;
a first insulating layer having a first pad via connected with the first metal layer, a capacitor via connected with the second metal layer, and an inductor via connected with the first or second metal layer;
a third metal layer including filling parts that fill the capacitor via and the inductor via, respectively, and providing a second circuit line formed on the first insulating layer and connected with the filling part of the capacitor via and an inductor line connected with the filling part of the inductor via;
a second insulating layer formed on the first insulating layer such that the second insulating layer covers the third metal layer and having a second pad via connected with the first pad via; and
a bonding pad formed at the first and second pad vias such that the bonding pad is connected with the first metal layer.

2. The device of claim 1, wherein the semiconductor substrate is a GaAs substrate or a high resistance silicon substrate.

3. The device of claim 1, wherein the first metal layer comprises a titanium (Ti) layer formed on the semiconductor substrate and a copper (Cu) layer formed on the Ti layer.

4. The device of claim 1, wherein at least one of the second and third metal layers comprises a seed metal layer and a plated layer formed on the seed metal layer.

5. The device of claim 4, wherein the seed metal layer is made of Ti/Cu and the plated layer is made of Cu.

6. The device of claim 1, wherein the inductor via is formed at a portion of the second metal layer to which the first metal layer is connected.

7. The device of claim 1, wherein the dielectric layer is formed on the semiconductor layer such that an area of the first metal layer which corresponds to the first pad via and an area of the first metal layer which is connected with the second metal layer are exposed.

8. The device of claim 1, wherein the dielectric layer comprises a silicon nitride film.

9. The device of claim 1, wherein at least one of the first and second insulating layers comprises benzocyclobutene (BCB).

10. The device of claim 1, wherein the bonding pad comprises nickel (Ni)/gold (Au).

11. The device of claim 1, further comprising shielding layer formed on an upper surface of the second insulating layer which corresponds to the inductor line or the second circuit line.

12. The device of claim 11, wherein the shielding layer is connected with the bonding pad as to be grounded.

13. A method for fabricating an RF semiconductor device, the method comprising:
preparing a semiconductor substrate;
forming a resistor film, provided as a resistor element, at one area of the semiconductor substrate;
forming a first metal layer, provided as a lower electrode film for a first circuit line to which the resistor film is connected and for a capacitor, on the semiconductor substrate;
forming a dielectric layer on the semiconductor substrate such that the first metal layer is exposed from one region;
forming a second metal layer, provided as an upper electrode film for a portion connected with the first metal layer and for the capacitor, on the dielectric layer;
forming a first insulating layer having a first pad via exposing the first metal layer, a via exposing the upper electrode film, and an inductor via exposing the second metal layer;
forming a third metal layer including filling parts that fill a capacitor via and the inductor via, respectively, and providing a second circuit line connected with the filling part of the capacitor via and an inductor line connected with the filling part of the inductor via on the first insulating layer;
forming a second insulating layer having a second pad via connected with the first pad via on the first insulating layer to cover the third metal layer; and
forming a bonding pad at the first and second pad vias such that the bonding pad is connected with the first metal layer.

14. The method of claim 13, wherein the semiconductor substrate is a GaAs substrate or a high resistance silicon substrate.

15. The method of claim 13, wherein forming of the first metal layer is made through a deposition process.

16. The method of claim 13, wherein the first metal layer comprises a titanium (Ti) layer formed on the semiconductor substrate and a copper (Cu) layer formed on the Ti layer.

17. The method of claim 13, wherein at least one of the second and third metal layers comprises a seed metal layer and a plated layer formed on the seed metal layer.

18. The method of claim 17, wherein the seed metal layer is made of Ti/Cu and the plated layer is made of Cu.

19. The method of claim 13, wherein the inductor via is formed at a portion of the second metal layer to which the first metal layer is connected.

20. The method of claim 13, wherein the dielectric layer is formed on the semiconductor layer such that an area of the first metal layer which corresponds to the first pad via and an area of the first metal layer which is connected with the second metal layer are exposed.

21. The method of claim 13, wherein the dielectric layer comprises a silicon nitride film.

22. The method of claim 13, wherein at least one of the first and second insulating layers comprises benzocyclobutene (BCB).

23. The method of claim 13, wherein the bonding pad comprises nickel (Ni)/gold (Au).

24. The method of claim 13, further comprising forming a shielding layer on an uppPr surface of the second insulating layer which corresponds to the inductor line or the second circuit line.

25. The method of claim 24, wherein the shielding layer is connected with the bonding pad so as to be grounded.
